(19) United States
(12) Patent Application Publication
(10) Pub. No.: US 2024/0213343 A1
(43) Pub. Date: Jun. 27, 2024

(54) Power Semiconductor Device and Method of Producing a Power Semiconductor Device

(71) Applicant: Infineon Technologies AG, Neubiberg (DE)

(72) Inventors: Roland Dietmüller, München (DE); Andreas Korzenietz, Putzbrunn (DE); Bernd Bitnar, Bannewitz (DE); Wolfgang Wagner, Villach (AT); Philip Christoph Brandt, Oberhaching (DE); Frank Hille, München (DE); Volodymyr Komarnitskyy, Villach (AT); Frank Pfirsch, München (DE); Franz Josef Niedernostheide, Hagen a.T.W. (DE); Marc Probst, Radeberg / OT Liegau-Augustusbad (DE)

(21) Appl. No.: 18/533,872

(22) Filed: Dec. 8, 2023

(30) Foreign Application Priority Data
Dec. 21, 2022 (DE) 102022214248.9

(51) Int. Cl. H01L 29/423; H01L 29/40; H01L 29/66; H01L 29/739; H01L 29/78

(52) U.S. Cl. CPC H01L 29/42364; H01L 29/401; H01L 29/4236; H01L 29/66348; H01L 29/66734; H01L 29/7397; H01L 29/7813

(57) ABSTRACT

A power semiconductor device includes a first region in an active region of a semiconductor body and including first trenches each having a first trench electrode electrically connected to a gate terminal and a first trench insulator. A second region includes second trenches each having a second trench electrode electrically connected to the gate terminal and a second trench insulator. At least one of the following applies: a minimal thickness of each second trench insulator amounts to at least 120% of a corresponding minimal thickness of each first trench insulator; an average thickness of the second trench insulators amounts to at least 120% of an average thickness of the first trench insulators; a trench bottom thickness of each second trench insulator amounts to at least 120% of a corresponding trench bottom thickness of each first trench insulator; a minimal breakdown voltage of each second trench insulator amounts to at least 120% of a minimal breakdown voltage of each first trench insulator.

### TECHNICAL FIELD

This specification refers to embodiments of a power semiconductor device and to embodiments of a method of producing a power semiconductor device. In particular, this specification refers to an IGBT with an internal gate resistor and a corresponding production method.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device usually comprises a semiconductor body configured to conduct a forward load current along a load current path between two load terminals of the device. The load current is typically conducted by means of an active region of the power semiconductor device. The active region is typically surrounded by an edge termination region, which is terminated by an edge of the chip.

In case of a controllable power semiconductor device, e.g., a transistor, the load current path may be controlled by means of an insulated electrode, commonly referred to as gate electrode. For example, upon receiving a corresponding control signal, e.g., from a driver unit via a control terminal of the device, the control electrode may set the power semiconductor device in one of a forward conducting state and a blocking state.

Such switching operations may be influenced, e.g., in terms of switching speed, such as turn-on durations and/or turn-off durations, based on the ohmic resistance of the transmission path relevant for the control signal. Said ohmic resistance is typically referred to as gate resistance and, correspondingly, said relevant transmission path is typically referred to as gate resistor. The gate resistor may be divided in an external part and a part integrated in the controllable power semiconductor device chip.

As the gate resistor, in particular its gate resistance, influences the switching operations of the device, it is a typical design goal to configure the gate resistor with a specific gate resistance to provide the device with defined device characteristics. Further, the gate resistor should be designed to not jeopardize the device reliability and with little area consumption to achieve a high power/area ratio.

### SUMMARY

The subject-matter of the independent claims is presented. Features of exemplary embodiments are defined in the dependent claims.

According to an embodiment, a power semiconductor device comprises: a semiconductor body coupled to a first load terminal at a first side and to a second load terminal at a second side that is opposite to the first side with respect to a vertical direction; an active region comprising a portion of the semiconductor body and configured to conduct a load current between the first load terminal and the second load terminal, wherein the active region is surrounded by an edge termination region; a gate terminal at the first side configured to receive a control signal for controlling the load current; a first region in the active region comprising a plurality of first trenches, each first trench including a first trench electrode electrically connected to the gate terminal and a first trench insulator electrically isolating the first trench electrode from the semiconductor body; a second region comprising a plurality of second trenches, each second trench including a second trench electrode electrically connected to the gate terminal and a second trench insulator electrically insulating the second trench electrode from the semiconductor body, wherein at least one of the following applies: a) a minimal thickness of each second trench insulator amounts to at least 120% of a corresponding minimal thickness of each first trench insulator; b) an average thickness of the second trench insulators amounts to at least 120% of an average thickness the first trench insulator; c) a thickness of each second trench insulator at the bottom of the respective second trench amounts to at least 120% of a corresponding thickness of each first trench insulator at the bottom of the respective first trench; d) a minimal breakdown voltage of each second trench insulator amounts to at least 120% of a minimal breakdown voltage of each first trench insulator.

According to a further embodiment, a method of producing a power semiconductor device is presented, wherein the method includes forming the following components: a semiconductor body coupled to a first load terminal at a first side and to a second load terminal at a second side that is opposite to the first side with respect to a vertical direction; an active region comprising a portion of the semiconductor body and configured to conduct a load current between the first load terminal and the second load terminal, wherein the active region is surrounded by an edge termination region; a gate terminal at the first side configured to receive a control signal for controlling the load current; a first region in the active region comprising a plurality of first trenches, each first trench including a first trench electrode electrically connected to the gate terminal and a first trench insulator electrically isolating the first trench electrode from the semiconductor body; a second region comprising a plurality of second trenches, each second trench including a second trench electrode electrically connected to the gate terminal and a second trench insulator electrically insulating the second trench electrode from the semiconductor body, and wherein at least one of the following applies: a) a minimal thickness of each second trench insulator amounts to at least 120% of a corresponding minimal thickness of each first trench insulator; b) an average thickness of the second trench insulators amounts to at least 120% of an average thickness the first trench insulator; c) a thickness of each second trench insulator at the bottom of the respective second trench amounts to at least 120% of a corresponding thickness of each first trench insulator at the bottom of the respective first trench; d) a minimal breakdown voltage of each second trench insulator amounts to at least 120% of a minimal breakdown voltage of each first trench insulator.

Those skilled in the art will recognize additional features and advantages upon reading the following detailed description, and upon viewing the accompanying drawings.

### BRIEF DESCRIPTION OF THE DRAWINGS

The parts in the FIGURES are not necessarily to scale, instead emphasis is being placed upon illustrating principles of the invention. Moreover, in the FIGURES, like reference numerals designate corresponding parts. In the drawings:

FIG. 1 schematically and exemplarily illustrates a section of a horizontal projection of a power semiconductor device in accordance with one or more embodiments;

FIG. 2 schematically and exemplarily illustrates, based on three sections of a vertical cross-section of a device being processed, steps of a power semiconductor device production method in accordance with one or more embodiments;

FIG. 3 schematically and exemplarily illustrates, based on two sections of a vertical cross-section of a device being processed, steps of a power semiconductor device production method in accordance with one or more embodiments.

FIG. 4 schematically and exemplarily illustrates an electrical diagram of the gate wiring of a power semiconductor device.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the FIGURES being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the FIGURES. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device, e.g., a power semiconductor device that may be used within a power converter or a power supply. Thus, in an embodiment, such device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell (e.g., a monolithically integrated cell of two anti-serially connected diodes), a monolithically integrated transistor cell, e.g., a monolithically integrated MOSFET or IGBT cell and/or derivatives thereof. Such diode/transistor cells may be integrated in a power semiconductor module. A plurality of such cells may constitute a cell field that is arranged within an active region of the power semiconductor device.

The term “blocking state” of the power semiconductor device may refer to conditions, when the semiconductor device is in a state configured for blocking a current flow through the semiconductor device, while an external voltage is applied. More particularly, the semiconductor device may be configured for blocking a forward current through the semiconductor device while a forward voltage bias is applied. In comparison, the semiconductor may be configured for conducting a forward current in a “conducting state” of the semiconductor device, when a forward voltage bias is applied. A transition between the blocking state and the conducting state may be controlled by a control electrode or, more particularly, a potential of the control electrode. Said electrical characteristics may, of course, only apply within a predetermined working range of the external voltage and the current density within the device. The term “forward biased blocking state” therefore may refer to conditions with the semiconductor device being in the blocking state while a forward voltage bias is applied.

The term “power semiconductor device” as used in this specification intends to describe a semiconductor device on a single chip with high voltage blocking and/or high current-carrying capabilities. In other words, such power semiconductor device is intended for high current, typically in the Ampere range, e.g., up to several ten or several hundred Ampere, and/or high voltages, typically above 15 V, more typically 100 V and above, e.g., up to at least 400 V or even more, e.g., up to at least 3 kV, or even up to 10 kV or more, depending on the respective application.

For example, the term “power semiconductor device” as used in this specification is not directed to logic semiconductor devices that are used for, e.g., storing data, computing data and/or other types of semiconductor based data processing.

The present specification in particular relates to a power semiconductor device embodied as a diode, a MOSFET or IGBT, i.e., a unipolar or bipolar power semiconductor transistor or diode or a derivate thereof, such as an RC IGBT.

For example, the power semiconductor device described below may be a single semiconductor chip, e.g., exhibiting a stripe cell configuration (or a cellular/needle cell configuration) and can be configured to be employed as a power component in a low-, medium- and/or high voltage application.

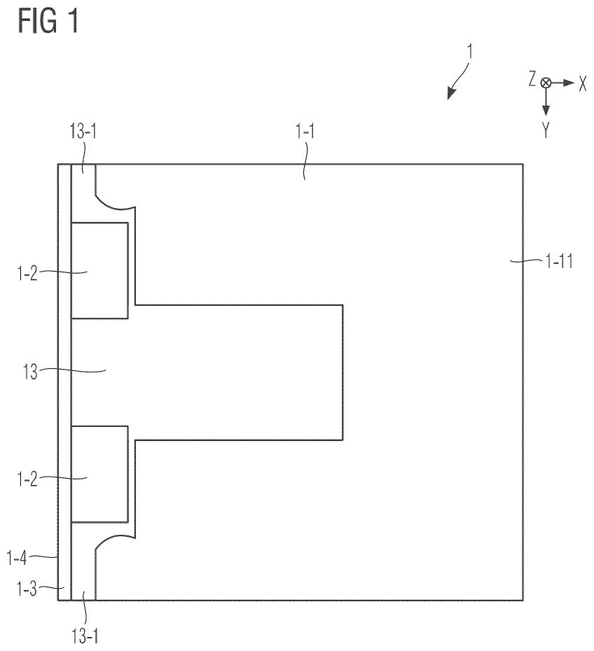

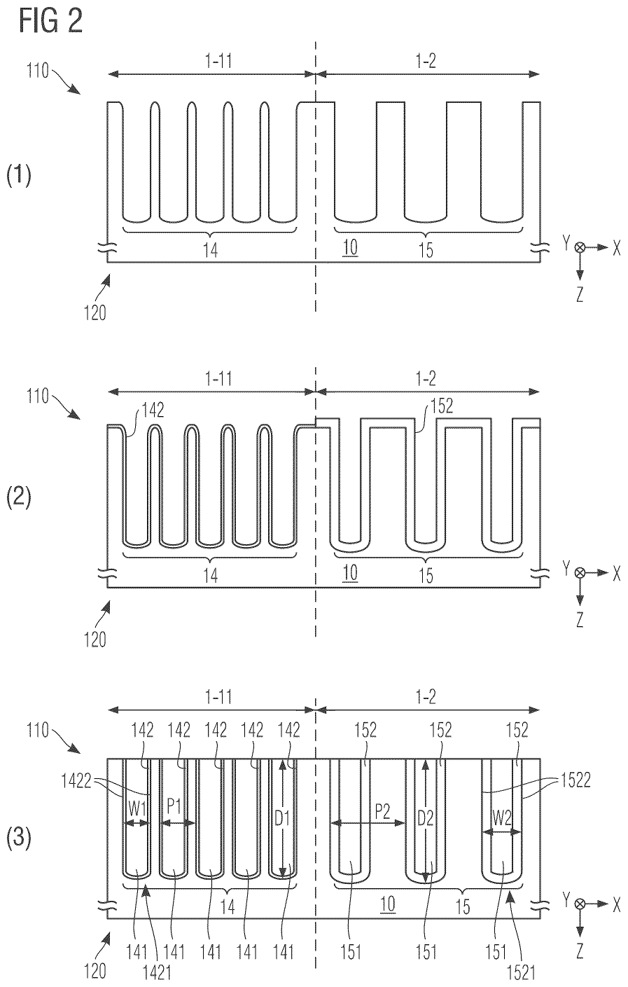

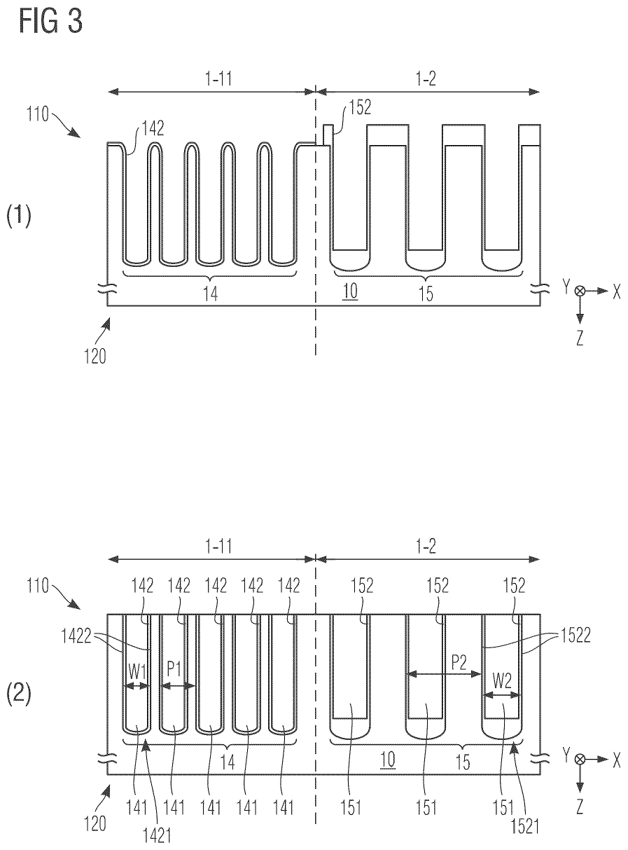

FIG. 1 schematically and exemplarily illustrates a section of a horizontal projection of a power semiconductor device 1 in accordance with one or more embodiments. The vertical cross-sections illustrated in FIG. 2 (3) and FIG. 3 (2) are additionally referred to in the following.

Accordingly, the power semiconductor device 1 comprises a semiconductor body 10 coupled to a first load terminal at a first side 110 and to a second load terminal at a second side 120 that is opposite to the first side 110 with respect to a vertical direction.

The power semiconductor device 1 may thus exhibit a vertical configuration according to which the load current flows substantially in parallel to the vertical direction Z.

The load terminals at the first and second side 110, 120 are not illustrated herein. E.g., the first load terminal may be a source (or emitter) terminal, and the second load terminal a drain (collector) terminal, e.g., in case of the power semiconductor device 1 being embodied as an IGBT.

The power semiconductor device 1 further comprises an active region 1-1 comprising a portion of the semiconductor body 10 and configured to conduct said load current between the first load terminal and the second load terminal, wherein the active region 1-1 is surrounded by an edge termination region 1-3 which in turn is terminated by a chip edge 1-4. Herein, the terms “active region” (sometimes also referred to as “cell field”), “edge termination region” and “chip edge” have the technical meanings the skilled person typically associates therewith in the context of power semiconductor devices such as IGBTs and MOSFETs and are hence not explained in further detail.

The power semiconductor device 1 further comprises a gate terminal 13 at the first side 110 configured to receive a control signal for controlling the load current. For example, the gate terminal 13 is a so-called gate pad. The gate terminal 13 may be contacted by a contact means, e.g., a bond wire, which may be electrically to an output of a driver unit providing the control signal.

The power semiconductor device 1 further comprises a first region 1-11—in the active region 1-1 comprising a plurality of first trenches 14 (cf. FIGS. 2 and 3). Each first trench 14 includes a first trench electrode 141 electrically connected to the gate terminal 13 and a first trench insulator 142 electrically isolating the first trench electrode 141 from the semiconductor body 10. In an embodiment, the first trenches 14 may be regarded as gate trenches with respective trench gate electrodes 141. The first trenches 14 are provided in the active region 1-1 to control the load current. E.g., adjacent to each of the first trenches, there may be arranged a channel structure (not illustrated herein) where a conductive channel may be induced. E.g., each of such channel structure comprises a semiconductor source region of the first conductivity type and a semiconductor body region of the second conductivity type which isolates the semiconductor source region from a semiconductor drift region of the first conductivity type. Both the semiconductor source region and the semiconductor body region may be electrically connected to the first load terminal. E.g., a first trench electrode 141 adjacent to such channel structure may be configured to induce a conductive inversion channel in the semiconductor body region if the first trench electrode 141 is subjected with a corresponding electrical potential. For example, the electrical potential of the trench electrodes 141 is controlled by applying a voltage between the control terminal 13 and the first load terminal.

As illustrated in FIGS. 2 and 3, the first trenches 15 may extend from the first side 110 along the vertical direction Z towards the second side 120. Besides the first trenches 14, which are control trenches, the first region 1-11 in the active region 1-1 may comprise further trench types, such as, for example, one or more source trenches (whose trench electrodes are electrically connected to the first load terminal), one or more floating trenches (whose trench electrodes are not electrically connected to a defined electrical potential), and/or one or more second control trenches (whose trench electrodes are electrically connected to a control potential different from the potential of the control terminal 13). Furthermore, besides mesas including a channel structure as described above, further mesa types may be included in the first region 1-11, e.g., mesas not electrically connected to the first load terminal 11 and/or mesas only including a semiconductor body region (but no source region) electrically connected to the first load terminal. Based on the different trench and mesa types, certain trench-mesa-patterns may be formed in the active region 1-1. However, the present disclosure is primarily related to the gate resistance/resistor which is rather independent from the chosen trench-mesa-pattern.

The power semiconductor device 1 further comprises a second region 1-2 comprising a plurality of second trenches 15. Each second trench includes a second trench electrode 151 electrically connected to the gate terminal 13 and a second trench insulator 152 electrically insulating the second trench electrode 151 from the semiconductor body 10. The power semiconductor device 1 may optionally comprise further trenches. The further trenches may comprise floating trenches with a trench electrode having a floating potential and/or source trenches being connected to source potential.

The second region 1-2 may or may not form a portion of the active region 1-1. The second region 1-2 may partially or entirely be a part of the active region 1-1. In another embodiment, the second region 1-2 is not part of the active region 1-1. In the latter case, for example, the second region 1-2 is not equipped with any channel structures for load current conduction.

For example, the second region 1-2—which may be a contiguous region or a spatially distributed region (as exemplarily illustrated in FIG. 1)—can be arranged at a peripheral region close to the edge termination region 1-3, i.e., close to the chip edge 1-4, e.g., between the gate terminal 13 and gate runners 13-1 used for connecting the first trench electrodes 141 to the gate terminal 13.

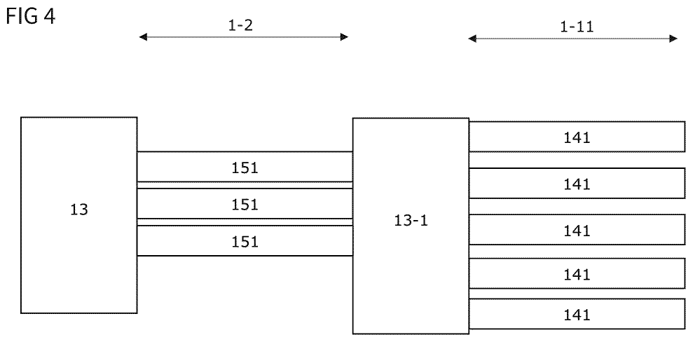

For example, the gate runner 13-1 is connected to the gate terminal 13 only via one or more of the second trench electrodes 151. For example, all of the first trench electrodes are connected to the gate runner 13-1. For example, all of the first trench electrodes 141 are connected to the gate terminal 13 via the gate runner 13-1. The gate runner 13-1 may be interposed between the first gate electrodes 141 and the second trench electrodes 151. For example, the connection may be in the following order: Gate terminal 13—second trench electrodes 151—gate runner 13-1—first trench electrodes 141 (cf. FIG. 4). The gate runner 13-1 may be an ohmic conductor, such as highly doped poly or a metal. Preferably, the gate runner 13-1 may be an ohmic metal. The gate runner 13-1 may be arranged above a first surface of the semiconductor body 10, while the trenches 14, 15 extend into the semiconductor body 10 from the first surface.

The second trenches 15 may exhibit dimensions, in terms of width and depth, comparable to the dimension of the first trenches 14 (with optional differences, as described below). As the first trenches 14, the second trenches 15 may extend from the first side 110 along the vertical direction Z towards the second side 120 (cf. FIGS. 2 and 3). Unlike the first region 1-11, the second region 1-2, in an embodiment, does not include further trench types.

In an embodiment, the second trench electrodes 151 are connected downstream with respect to the gate terminal 13 and upstream with respect to the first trench electrodes 141. That is, the design of the second trenches 15 influences the effective gate resistance. As the gate resistance is in particular influenced by the design of the second trench electrodes 151, the gate resistor of the power semiconductor device 1 may be regarded as an internal gate resistor. As mentioned above, the gate resistor may comprise a part external and an internal part. The internal gate resistor may represent the internal part of the gate resistor. The internal gate resistor may, optionally, be accompanied by an external gate resistor connected in series. The internal gate resistor may connect the gate terminal 13 and the first trench electrodes 141.

In an embodiment, at least one of the following applies:
a) a minimal thickness of each second trench insulator 152 amounts to at least 120%, or to at least 150%, or to at least 200% of a corresponding minimal thickness of each first trench insulator 142;
b) an average thickness of the second trench insulators 152 amounts to at least 120% of an average thickness the first trench insulator 142;
c) a thickness of each second trench insulator 152 at the bottom of the respective second trench 15 amounts to at least 120% of a corresponding thickness of each first trench insulator 142 at the bottom of the respective first trench 14;
d) a minimal breakdown voltage of each second trench insulator 152 amounts to at least 120% of a minimal breakdown voltage of each first trench insulator 142 for the static case.

As indicated above, one, two or more than two of the features a) to d) may be implemented for the power semiconductor device 1.

The above-described embodiment includes the recognition that the internal gate resistors based on trench electrodes may be subjected to comparatively higher transient voltages compared to the trenches 14, in particular at the bottom of the trench. Therefore, even though efficient in terms of processing complexity, forming the second trenches 15 identical to the first trenches 14, may be inappropriate. Rather, due to the possibly higher transient voltages, the second trench insulator 152 should be designed to exhibit better isolation as compared to the first trench insulator 142.

In the following, further optional features of the power semiconductor device 1 will be described, wherein reference is made to each of FIGS. 1 to 3.

The power semiconductor device 1 may be a bipolar semiconductor device, e.g., an IGBT (wherein the IGBT can be, without being limited thereto, an npnp IGBT with an n-inversion channel or a pnpn IGBT with an p-inversion channel) or an RC IGBT. Thus, the drift region may be of the first conductivity type and for example extend along the vertical direction Z until adjoining, either directly or via a field stop layer, a collector region (not illustrated) of the second conductivity type, wherein said collector region can be electrically connected to the second load terminal. If configured, for example, as an RC IGBT, the device 1 may further comprise one or more second emitter regions (not illustrated) of the first conductivity type, wherein said second emitter region(s) can be electrically connected to the second load terminal.

As already indicated above, in an embodiment, the first trench electrodes 141 are electrically connected to the gate terminal 13 at least via the second trench electrodes 151. That is, the second trench electrodes 151 may serve as internal gate resistor.

The total extension of the first region 1-11 may be greater than the total extension of the second region 1-2. For example, the first region 1-11 (which is part of the active region 1-1) has a total horizontal area amounting to at least 70% of the total horizontal area of the active region 1-1. In an embodiment, the active region 1-1 may even consist of the first region 1-11, in which case the total horizontal areas would be of identical size. Furthermore, the second region 1-2 can have a total horizontal area corresponding to at least 5% of the total horizontal area of the active region 1-1. In case the second region 1-2 does not or only partially contribute to the active region 1-1, i.e., to a portion of the device 1 used for load current conduction, a typical design goal would be to keep the second region 1-2 as small as possible so as to no “waste” any volume that could be used for the active region. Hence, in an embodiment, the second region 1-2 can have a total horizontal area corresponding to no more than 1% of the total horizontal area of the active region 1-1.

As also already indicated above, the first region 1-11 can be configured, at least based on the first trench electrodes 141, for controlling the load current. To this end, adjacent to each or at least some of the first trenches, said channel structures may be implemented. By contrast, the second region 1-2 must not necessarily be designed for load current conduction and may hence be configured without any semiconductor source region.

Rather, in an embodiment, the second region 1-2 is configured, based on the second trench electrodes 151, to form a specific internal gate resistor. Based on the specific internal gate resistor, the power semiconductor device may be provided with specific switching characteristics and, due to the “thicker”/“stronger” second trench insulator 152, with improved reliability.

In each of the first trenches 14 and the second trenches 15, the first trench insulator 142 or, respectively, the second trench insulator 152 may exhibit a thickness that is preferably symmetric with respect to center vertical plane. This optional aspect is illustrated in FIG. 2-(3) and in FIG. 3-(2). As illustrated, at the trench bottom, the trench insulator 142/152 may be designed with the same (FIG. 2) or a greater (FIG. 3) thickness. In either case, the trench insulator 142/152 is configured with mirror symmetric thickness with respect to a center vertical plane (in parallel to the vertical direction Z and the second lateral direction Y).

Furthermore, in an embodiment, in each of the first trenches 14 and the second trenches 15, the first trench insulator 142 or, respectively, the second trench insulator 152 exhibits an at least essentially constant thickness both at the trench sidewalls 1422; 1522 and at the trench bottom 1421; 1521. An at least essentially constant thickness may be defined as a constant thickness with only small (e.g. process-induced) variations of less than 10% or even less than 5% along the trench sidewall. This variant is illustrated in FIG. 2-(3). By contrast, in order to in particular protect the trench bottom, in an embodiment, in each of the second trenches 15, the second trench insulator 152 exhibits, at the trench bottom 1521, a thickness that is greater as the thickness of the second trench insulator 152 at the trench sidewalls 1522. The latter variant is illustrated in FIG. 3-(2). E.g., the average thickness of the second trench insulator 152 at the trench bottom 1521 amounts to at least 110%, or at least 120,% or at least 150% of the average thickness of the second trench insulator 152 at the trench sidewalls 1522.

In an embodiment, cf. FIG. 2, an average width W2 of the second trenches 15 along the first lateral direction X amounts to at least 120%, or at least 135%, or at least 150% of an average width W1 of the first trenches 14 along the first lateral direction X. In terms of processing, the wider trench width W2 may facilitate providing the second trench insulator 152 with a thickness greater than the thickness of the first trench insulator 142. Furthermore, a second trench pitch P2 in the second region 1-2 may amount to at least at least 120%, or at least 135%, or at least 150% of a first trench pitch P1 in the first region 1-11. An average width of the second trench electrodes 151 along the first lateral direction X can be within a range of 95% to 105% of an average width of the first trench electrodes 141 along the first lateral direction X. In other words, the second trench electrodes 151 may exhibit the substantially same width as the first trench electrodes 141.

Furthermore, in an embodiment, an average depth D2 of the second trenches 15 along the vertical direction Z is within a range of 85% to 115% or within a range of 95% to 105% of an average depth D1 of the first trenches 14 along the vertical direction Z. In other words, the second trenches 15 may exhibit the substantially same total vertical extension as the first trenches 14. Likewise, the second trench electrodes 151 may exhibit the substantially same total vertical extension as the first trench electrodes 141, wherein in the embodiment illustrated in FIG. 3, the second trench electrodes are slightly shorter due to the increased second trench insulator thickness at the trench bottom 1521.

In an embodiment, the power semiconductor device 1 is devoid of a gate resistor external of the path between the gate terminal 13 and the first trench electrodes 141. Said path in particular includes the second trench electrodes 151. For example, the device 1 is not equipped with another additional gate resistor external of this path. Rather, the gate resistance is predominantly formed by the second trench electrodes 151.

Both the first trench electrodes 141 and the second trench electrodes 151 may comprise or consist of poly-crystalline silicon, Si. The first trench insulators 142 may comprise a thermally grown oxide, e.g., silicon oxide, SiO2, and may exhibit a thickness in the range of 10 nm to 200 nm. The second trench insulators 152 comprise a deposited oxide, e.g., silicon oxide, nitride, oxynitride, tetraethoxysilane, TEOS, and may exhibit a thickness greater than 200 nm or greater than 250 nm.

The first trench insulator 142 can comprise more than one layer, e.g., two or more layers of different materials. The second trench insulator 152 can comprise more than one layer, e.g., two or more layers of different materials.

In an embodiment, the first region 1-11 does not comprise any second trench 15. Additionally or alternatively, the second region 1-2 does not comprise any first trench 14.

In a further non-illustrated embodiment, the power semiconductor device comprises a plurality of second regions 1-2. For example, the second regions 1-2 differ in the total gate resistance formed by the respective second region. Furthermore, a first subset of the first trench electrodes 141 may be connected with the gate terminal 13 via a first one of the second regions 1-2, a second subset of the first trench electrodes 141 may be connected with the gate terminal 13 via a second one of the second regions 1-2, and so on. Thereby, different subregions of the first regions 1-11 may be controlled based on the same control signal, wherein the subregions differ from each other in their switching characteristics due to the different gate resistances formed by the second regions 1-2.

Presented herein are also methods of producing a power semiconductor device.

According to a further embodiment, a method of producing a power semiconductor device is presented, wherein the method includes forming the following components: a semiconductor body coupled to a first load terminal at a first side and to a second load terminal at a second side that is opposite to the first side with respect to a vertical direction; an active region comprising a portion of the semiconductor body and configured to conduct a load current between the first load terminal and the second load terminal, wherein the active region is surrounded by an edge termination region; a gate terminal at the first side configured to receive a control signal for controlling the load current; a first region in the active region comprising a plurality of first trenches, each first trench including a first trench electrode electrically connected to the gate terminal and a first trench insulator electrically isolating the first trench electrode from the semiconductor body; a second region comprising a plurality of second trenches, each second trench including a second trench electrode electrically connected to the gate terminal and a second trench insulator electrically insulating the second trench electrode from the semiconductor body, and wherein at least one of the following applies: a) a minimal thickness of each second trench insulator amounts to at least 120% of a corresponding minimal thickness of each first trench insulator; b) an average thickness of the second trench insulators amounts to at least 120% of an average thickness the first trench insulator; c) a thickness of each second trench insulator at the bottom of the respective second trench amounts to at least 120% of a corresponding thickness of each first trench insulator at the bottom of the respective first trench; d) a minimal breakdown voltage of each second trench insulator amounts to at least 120% of a minimal breakdown voltage of each first trench insulator.

Embodiments of the method described above correspond to the embodiments of the power semiconductor device 1 described above. In so far, it is referred to the aforesaid.

In an example, forming the first trenches 14 and the second trenches 15 includes a joint trench etch processing step based on a lithographic mask including openings of different widths. Thereby, the second trenches 15 can be provided with the larger trench width W2.

Furthermore, forming the first trench electrodes 141 and the second trench electrodes 151 may include a joint electrode material deposition processing step or two separate electrode material deposition processing steps.

E.g., referring to FIG. 2-(1), the semiconductor body 10 is provided and the first side is subjected to a trench etch processing step for forming first recesses in the first region 1-11 corresponding to the first trenches 14 and second recesses in the second region 1-2 corresponding to the second trenches 15. The second recesses may exhibit a larger width than the first recesses.

Regarding FIGS. 2-(2) and 3-(1), an SiO2 layer may be provided in the first region 1-11 for forming the first trench insulators 142, with a thickness of 50 to 200 nm, and a TEOS layer may be provided in the second region 1-2 for forming the second trench insulator 152, e.g., with a thickness of 300 nm. To provide for a thicker trench insulator at the trench bottom 1521 (cf. FIG. 3-(1)), an anisotropically grown oxide layer, e.g., a high-density-plasma, HDP, oxide may be formed, yielding a larger insulator thickness at the trench bottom 1521 and a smaller insulator thickness at the trench sidewalls 1522.

Referring to FIGS. 2-(3) and 3-(2), a polishing processing step may be carried out to remove the first trench insulator 142 and the second trench insulator at the first side 110.

In the above, embodiments pertaining to power semiconductor device, such as MOSFETs, IGBTs, RC IGBTs and derivatives thereof, and corresponding processing methods were explained. For example, these power semiconductor devices are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixC1-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the FIGURES. Further, terms such as “first”, “second”, and the like, are also used to describe various elements, regions, sections, etc. and are also not intended to be limiting. Like terms may refer to like elements throughout the description.

As used herein, the terms “having”, “containing”, “including”, “comprising”, “exhibiting” and the like are open ended terms that indicate the presence of stated elements or features, but do not preclude additional elements or features.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A power semiconductor device, comprising:
a semiconductor body coupled to a first load terminal at a first side and to a second load terminal at a second side that is opposite to the first side with respect to a vertical direction;
an active region comprising a portion of the semiconductor body and configured to conduct a load current between the first load terminal and the second load terminal, wherein the active region is surrounded by an edge termination region;
a gate terminal at the first side and configured to receive a control signal for controlling the load current;
a first region in the active region and comprising a plurality of first trenches, each first trench including a first trench electrode electrically connected to the gate terminal and a first trench insulator electrically isolating the first trench electrode from the semiconductor body;
a second region comprising a plurality of second trenches, each second trench including a second trench electrode electrically connected to the gate terminal and a second trench insulator electrically insulating the second trench electrode from the semiconductor body,
wherein at least one of the following applies:
a) a minimal thickness of each second trench insulator amounts to at least 120% of a corresponding minimal thickness of each first trench insulator;
b) an average thickness of the second trench insulators amounts to at least 120% of an average thickness the first trench insulators;
c) a thickness of each second trench insulator at a bottom of the respective second trench amounts to at least 120% of a corresponding thickness of each first trench insulator at a bottom of the respective first trench;
d) a minimal breakdown voltage of each second trench insulator amounts to at least 120% of a minimal breakdown voltage of each first trench insulator.

2. The power semiconductor device of claim 1, wherein the first trench electrodes are electrically connected to the gate terminal at least via the second trench electrodes.

3. The power semiconductor device of claim 1, wherein in a horizontal cross-section, the first region has a total horizontal area amounting to at least 70% of a total horizontal area of the active region and the second region has a total horizontal area corresponding to at least 5% of the total horizontal area of the active region.

4. The power semiconductor device of claim 1, wherein the first region is configured, at least based on the first trench electrodes, to control the load current, and wherein the second region does not comprise any semiconductor source region.

5. The power semiconductor device of claim 1, wherein the second region is configured, based on the second trench electrodes, to form a specific internal gate resistor.

6. The power semiconductor device of claim 1, wherein in each of the first trenches and the second trenches, the first trench insulator or, respectively, the second trench insulator has a thickness that is symmetric with respect to a center vertical plane.

7. The power semiconductor device of claim 1, wherein in each of the first trenches and the second trenches, the first trench insulator or, respectively, the second trench insulator has an at least essentially constant thickness both at sidewalls of the respective trench and at the bottom of the respective trench.

8. The power semiconductor device of claim 1, wherein in each of the second trenches, the second trench insulator exhibits, at the bottom of the trench, a thickness that is greater as a thickness of the second trench insulator at sidewalls of the trench.

9. The power semiconductor device of claim 1, wherein an average width of the second trenches along a first lateral direction amounts to at least 120% of an average width of the first trenches along the first lateral direction.

10. The power semiconductor device of claim 1, wherein an average depth of the second trenches along the vertical direction is within a range of 85% to 115% of an average depth of the first trenches along the vertical direction.

11. The power semiconductor device of claim 1, wherein the power semiconductor device is devoid of a gate resistor external of a path between the gate terminal and the first trench electrodes.

12. The power semiconductor device of claim 1, wherein both the first trench electrodes and the second trench electrodes comprise poly-crystalline silicon, Si.

13. The power semiconductor device of claim 1, wherein the first trench insulators comprise a thermally grown oxide.

14. The power semiconductor device of claim 1, wherein the second trench insulators comprise a deposited oxide.

15. The power semiconductor device of claim 1, wherein a trench pitch in the second region amounts to at least 120% of a trench pitch in the first region.

16. The power semiconductor device of claim 1, wherein an average width of the second trench electrodes along the first lateral direction is within a range of 95% to 105% of an average width of the first trench electrodes along the first lateral direction.

17. The power semiconductor device of claim 1, wherein the power semiconductor device is one of a MOSFET, an IGBT, a derivative of a MOSFET, or a derivative of an IGBT.

18. The power semiconductor device of claim 1, further comprising a gate runner, wherein the gate runner is connected to the gate terminal only via one or more of the second trench electrodes.

19. The power semiconductor device of claim 18, wherein all of the first trench electrodes are directly connected to the gate runner.

20. The power semiconductor device of claim 18, wherein all of the first trench electrodes are connected to the gate terminal via the gate runner, and wherein the gate runner is interposed between the first gate electrodes and the second trench electrodes.

21. The power semiconductor device of claim 18, wherein the gate runner comprises an ohmic metal.

22. A method of producing a power semiconductor device, the method comprising:
forming a semiconductor body coupled to a first load terminal at a first side and to a second load terminal at a second side that is opposite to the first side with respect to a vertical direction;
forming an active region comprising a portion of the semiconductor body and configured to conduct a load current between the first load terminal and the second load terminal, wherein the active region is surrounded by an edge termination region;
forming a gate terminal at the first side and configured to receive a control signal for controlling the load current;
forming a first region in the active region and comprising a plurality of first trenches, each first trench including a first trench electrode electrically connected to the gate terminal and a first trench insulator electrically isolating the first trench electrode from the semiconductor body; and
forming a second region comprising a plurality of second trenches, each second trench including a second trench electrode electrically connected to the gate terminal and a second trench insulator electrically insulating the second trench electrode from the semiconductor body,
wherein at least one of the following applies:
a) a minimal thickness of each second trench insulator amounts to at least 120% of a corresponding minimal thickness of each first trench insulator;
b) an average thickness of the second trench insulators amounts to at least 120% of an average thickness the first trench insulators;
c) a thickness of each second trench insulator at a bottom of the respective second trench amounts to at least 120% of a corresponding thickness of each first trench insulator at a bottom of the respective first trench;
d) a minimal breakdown voltage of each second trench insulator amounts to at least 120% of a minimal breakdown voltage of each first trench insulator.

23. The method of claim 22, wherein forming the first trenches and the second trenches comprises a joint trench etch processing step based on a lithographic mask including openings of different widths.

24. The method of claim 22, wherein forming the first trench electrodes and the second trench electrodes comprises a joint electrode material deposition processing step or two separate electrode material deposition processing steps.
